(19) United States
(12) Patent Application Publication
(10) Pub. No.: US 2026/0082583 A1
(43) Pub. Date: Mar. 19, 2026

(54) MAGNETIC MEMORY DEVICE

(71) Applicant: Kioxia Corporation, Tokyo (JP)

(72) Inventor: Yuuichi KAMIMUTA, Seoul (KR)

(73) Assignee: Kioxia Corporation, Tokyo (JP)

(21) Appl. No.: 19/322,737

(22) Filed: Sep. 9, 2025

(30) Foreign Application Priority Data
Sep. 17, 2024 (JP) 2024-160358

(51) Int. Cl. H10B 61/00; H10N 50/01; H10N 50/10

(52) U.S. Cl. CPC H10B 61/10; H10N 50/01; H10N 50/10

(57) ABSTRACT

According to one embodiment, a magnetic memory device includes a magnetoresistance effect element including a first magnetic layer having a variable magnetization direction, a second magnetic layer having a fixed magnetization direction, and a non-magnetic layer provided between the first magnetic layer and the second magnetic layer, and having a structure in which the first magnetic layer, the second magnetic layer, and the non-magnetic layer are stacked, an electrode having an upper surface connected to a lower surface of the magnetoresistance effect element, and a first insulating layer formed of an amphoteric oxide, which surrounds a side surface of the electrode and has an upper surface at a position lower than that of the upper surface of the electrode.

### CROSS-REFERENCE TO RELATED APPLICATIONS

This application is based upon and claims the benefit of priority from Japanese Patent Application No. 2024-160358, filed Sep. 17, 2024, the entire contents of which are incorporated herein by reference.

### FIELD

Embodiments described herein relate generally to a magnetic memory device.

### BACKGROUND

Magnetic memory devices in which a plurality of multiple magnetoresistance effect elements are integrated on a semiconductor substrate have been proposed.

### BRIEF DESCRIPTION OF THE DRAWINGS

FIG. 1 is a perspective view schematically showing a basic structure of a magnetic memory device according to the first embodiment.

FIGS. 2A and 2B are cross-sectional views each schematically showing the basic structure of the magnetic memory device according to the first embodiment.

FIG. 3A is a cross-sectional view schematically showing a structure of a main body of a magnetoresistance effect element of the magnetic memory device according to the first embodiment.

FIG. 3B is a cross-sectional view schematically showing a structure of a modified example of a main body of the magnetoresistance effect element in the magnetic memory device according to the first embodiment.

FIG. 4 is a diagram schematically showing current-voltage characteristics of a selector of the magnetic memory device according to the first embodiment.

FIG. 5 is a diagram schematically showing a relationship between a pattern of a lower surface of the magnetoresistance effect element and a pattern of an upper surface of a top electrode of the selector in the magnetic memory device according to the first embodiment.

FIGS. 6A and 6B are cross-sectional views each schematically showing part of a method of manufacturing the magnetic memory device according to the first embodiment.

FIGS. 7A and 7B are cross-sectional views each schematically showing part of the method of manufacturing the magnetic memory device according to the first embodiment.

FIGS. 8A and 8B are cross-sectional views each schematically showing part of the method of manufacturing the magnetic memory device according to the first embodiment.

FIGS. 9A and 9B are cross-sectional views each schematically showing part of the method of manufacturing the magnetic memory device according to the first embodiment.

FIGS. 10A and 10B are cross-sectional views each schematically showing part of the method of manufacturing the magnetic memory device according to the first embodiment.

FIGS. 11A and 11B are cross-sectional views each schematically showing part of the method of manufacturing the magnetic memory device according to the first embodiment.

FIGS. 12A and 12B are cross-sectional views each schematically showing a basic structure of a magnetic memory device according to the second embodiment.

FIGS. 13A and 13B are cross-sectional views each schematically showing part of a method of manufacturing the magnetic memory device according to the second embodiment.

FIGS. 14A and 14B are cross-sectional views each schematically showing part of the method of manufacturing the magnetic memory device according to the second embodiment.

FIGS. 15A and 15B are cross-sectional views each schematically showing part of the method of manufacturing the magnetic memory device according to the second embodiment.

FIGS. 16A and 16B are cross-sectional views each schematically showing part of the method of manufacturing the magnetic memory device according to the second embodiment.

FIGS. 17A and 17B are cross-sectional views each schematically showing part of the method of manufacturing the magnetic memory device according to the second embodiment.

FIGS. 18A and 18B are cross-sectional views each schematically showing part of the method of manufacturing the magnetic memory device according to the second embodiment.

FIGS. 19A and 19B are cross-sectional views each schematically showing a basic structure of a magnetic memory device according to the third embodiment.

FIG. 20 is a diagram schematically showing a relationship between a pattern of a lower surface of a magnetoresistance effect element and a pattern of an upper surface of a wiring line in the magnetic memory device according to the third embodiment.

FIGS. 21A and 21B are cross-sectional views each schematically showing part of a method of manufacturing the magnetic memory device according to the third embodiment.

FIGS. 22A and 22B are cross-sectional views each schematically showing part of the method of manufacturing the magnetic memory device according to the third embodiment.

FIGS. 23A and 23B are cross-sectional views each schematically showing part of the method of manufacturing the magnetic memory device according to the third embodiment.

FIGS. 24A and 24B are cross-sectional views each schematically showing part of the method of manufacturing the magnetic memory device according to the third embodiment.

FIGS. 25A and 25B are cross-sectional views each schematically showing part of the method of manufacturing the magnetic memory device according to the third embodiment.

FIGS. 26A and 26B are cross-sectional views each schematically showing part of the method of manufacturing the magnetic memory device according to the third embodiment.

### DETAILED DESCRIPTION

In general, according to one embodiment, a magnetic memory device includes a magnetoresistance effect element including a first magnetic layer having a variable magnetization direction, a second magnetic layer having a fixed magnetization direction, and a non-magnetic layer provided between the first magnetic layer and the second magnetic layer, and having a structure in which the first magnetic layer, the second magnetic layer, and the non-magnetic layer are stacked, an electrode having an upper surface connected to a lower surface of the magnetoresistance effect element, and a first insulating layer formed of an amphoteric oxide, which surrounds a side surface of the electrode and has an upper surface at a position lower than that of the upper surface of the electrode.

Embodiments will now be described with reference to the accompanying drawings.

### First Embodiment

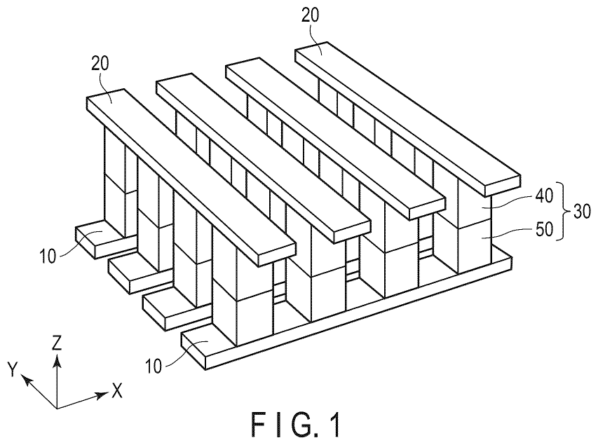

FIG. 1 is a perspective view schematically showing the basic structure of the magnetic memory device according to the first embodiment.

The magnetic memory device shown in FIG. 1 includes a plurality of wiring lines 10 each extending along an X direction, a plurality of wiring lines 20 each extending along a Y direction, and a plurality of memory cells 30 connected between the plurality of wiring lines 10 and the plurality of wiring lines 20, respectively.

The wiring lines 10 or the wiring lines 20 correspond to word lines, and the others of the wiring lines 10 and the wiring lines 20 correspond to bit lines.

Each of the memory cells 30 includes a magnetoresistance effect element 40 and a selector (switching element) 50. The magnetoresistance effect element 40 and the selector 50 are connected in series between a respective wiring line 10 and a respective wiring line 20 and are stacked along a Z direction. Further, the selector 50 is located on a lower layer side of the magnetoresistance effect element 40.

Note that the X direction, Y direction, and Z direction mutually intersect each other. More specifically, the X direction, Y direction, and Z direction are orthogonal each other.

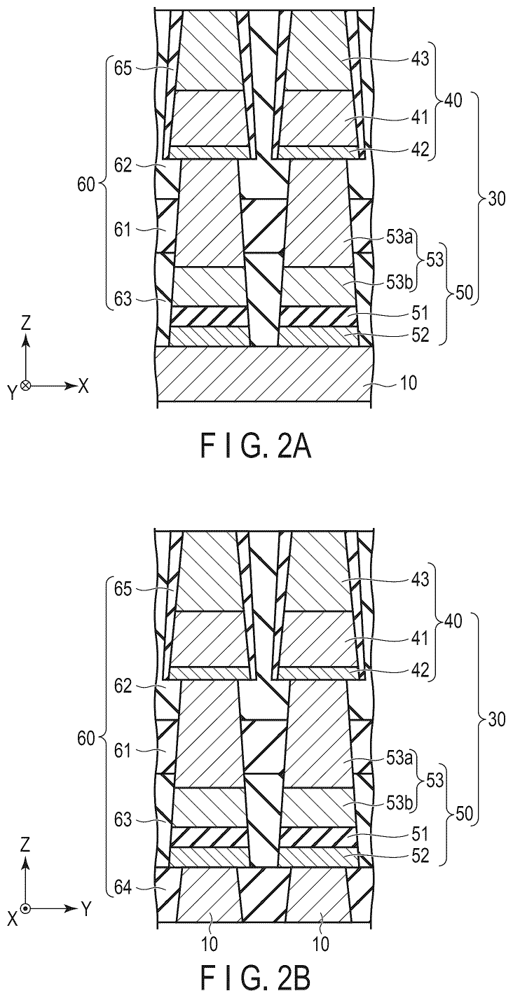

FIGS. 2A and 2B are schematic cross-sectional views each showing a basic structure of the magnetic memory device according to this embodiment. FIG. 2A is a cross-sectional view parallel to the X direction, and FIG. 2B is a cross-sectional view parallel to the Y direction.

The structure shown in FIGS. 2A and 2B is located on an under region (not shown) including the semiconductor substrate (not shown) and the like, and includes a memory cell 30 comprising a wiring line 10, and a memory cell 30 comprising a magnetoresistance effect element 40 and a selector (switching element) 50, and an insulating region 60. Note that although not shown in FIGS. 2A and 2B, the wiring line 20 as shown in FIG. 1 is usually provided on the upper layer side of the memory cell 30.

As already mentioned, the memory cell 30 has a structure in which the magnetoresistance effect element 40 and the selector 50 are stacked along the Z direction, and the selector 50 is located on the lower layer side of the magnetoresistance effect element 40.

The magnetoresistance effect element 40 includes a bottom electrode 42, a top electrode 43, and the main body 41 of the magnetoresistance effect element disposed between the bottom electrode 42 and the top electrode 43, and has a structure in which the main body 41 of the magnetoresistance effect element, the bottom electrode 42, and the top electrode 43 are stacked along the Z direction.

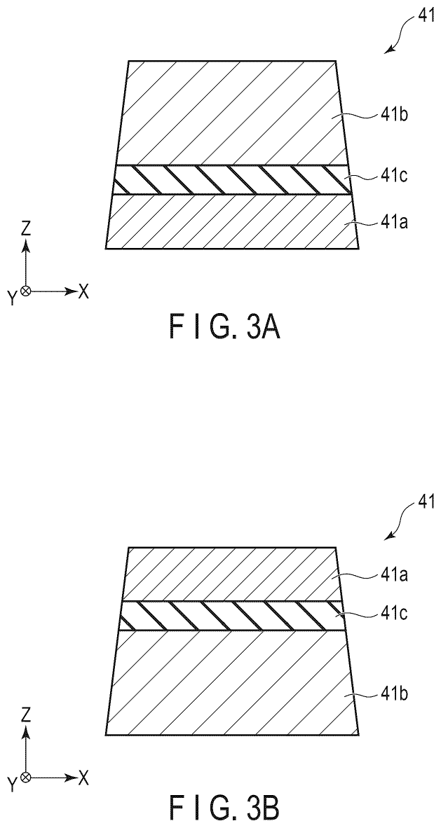

FIG. 3A is a cross-sectional view schematically showing the structure of the main body 41 of the magnetoresistance effect element.

The main body 41 of the magnetoresistance effect element is a magnetic tunnel junction (MTJ) element, which includes a storage layer (first magnetic layer) 41a, a reference layer (second magnetic layer) 41b, and a tunnel barrier layer (nonmagnetic layer) 41c, and has a structure in which the storage layer 41a, the reference layer 41b, and the tunnel barrier layer 41c are stacked along the Z direction.

The storage layer 41a is a ferromagnetic layer having a variable magnetization direction, and is formed, for example, from a CoFeB layer containing cobalt (Co), iron (Fe), and boron (B). Note that the term “variable magnetization direction” means that the magnetization direction changes for to a predetermined write current.

The reference layer 41b is a ferromagnetic layer having a fixed magnetization direction, and includes, for example, a CoFeB layer containing cobalt (Co), iron (Fe), and boron (B), and a superlattice layer of cobalt (Co) and platinum (Pt). Note that the term “fixed magnetization direction” means that the magnetization direction does not change for a predetermined write current.

The tunnel barrier layer 41c is an insulating layer disposed between the storage layer 41a and the reference layer 41b, and is formed, for example, from a MgO layer containing magnesium (Mg) and oxygen (O).

Note that the main body 41 of the magnetoresistance effect element may further include, for example, a shift canceling layer that cancels the electric field applied from the reference layer 41b to the storage layer 41a.

When the magnetization direction of the storage layer 41a is parallel to the magnetization direction of the reference layer 41b, the main body 41 of the magnetoresistance effect element is in a low-resistance state having a relatively low resistance. When the magnetization direction of the storage layer 41a is antiparallel to the magnetization direction of the reference layer 41b, the main body 41 of the magnetoresistance effect element is in a high-resistance state having a relatively high resistance. Therefore, the main body 41 of the magnetoresistance effect element can store binary data according to its resistance state.

The main body 41 of the magnetoresistance effect element is a spin transfer torque (STT) type element and has perpendicular magnetization. That is, the magnetization direction of the storage layer 41a is perpendicular to the film surface, and the magnetization direction of the reference layer 41b is perpendicular to the film surface.

FIG. 3B is a cross-sectional view schematically showing the structure of a modified example of the main body 41 of the magnetoresistance effect element.

The main body 41 of the magnetoresistance effect element shown in FIG. 3A is a bottom-free type element in which the storage layer 41a is located on the lower layer side of the reference layer 41b, but as shown in FIG. 3B, a top-free type element in which the storage layer 41a is located on the upper layer side of the reference layer 41b may as well be used.

The bottom electrode 42 functions as the bottom electrode of the magnetoresistance effect element 40 and is formed of a conductive material containing an element selected from titanium (Ti), zirconium (Zr), hafnium (Hf), vanadium (V), niobium (Nb), tantalum (Ta), scandium (Sc), yttrium (Y), and lanthanoid elements.

Specifically, the bottom electrode 42 may as well be formed from one or more of the above-listed elements, or from a compound of one or more of the above-listed elements and some other element (for example, nitrogen (N), carbon (C), or boron (B)), (that is, for example, a nitride, carbide, or boride of one or more of the above-listed elements).

The top electrode 43 functions as the top electrode of the magnetoresistance effect element 40 and is formed of a conductive material, and includes a cap layer, a hard mask layer and the like.

The selector 50 is a two-terminal switching element, which comprises a selector material layer (switching material layer) 51, a bottom electrode 52, and a top electrode 53, and has a structure in which the selector material layer 51, the bottom electrode 52, and the top electrode 53 are stacked along the Z direction.

The selector material layer 51 is disposed between the bottom electrode 52 and the top electrode 53 and is formed, for example, from a silicon oxide containing arsenic (As).

The bottom electrode 52 functions as the bottom electrode of the selector 50 and is formed, for example, from a conductive material such as titanium nitride (TiN).

The top electrode 53 functions as the top electrode of the selector 50, has an upper surface connected to the lower surface of the magnetoresistance effect element 40, and includes an electrode portion (first electrode portion) 53a and an electrode portion (second electrode portion) 53b stacked along the Z direction.

The electrode portion 53a is connected to the lower surface of the magnetoresistance effect element 40 and is formed from a conductive material such as titanium nitride (TiN).

The electrode portion 53b is connected to the lower surface of the electrode portion 53a and is formed from a material different from that of the electrode portion 53a. Specifically, the electrode portion 53b is formed from a conductive material containing carbon (C). That is, the electrode portion 53b may as well be formed solely from carbon or from a compound of carbon and some other element. When the electrode portion 53b is formed from a material containing carbon, a selector 50 having excellent characteristics can be obtained.

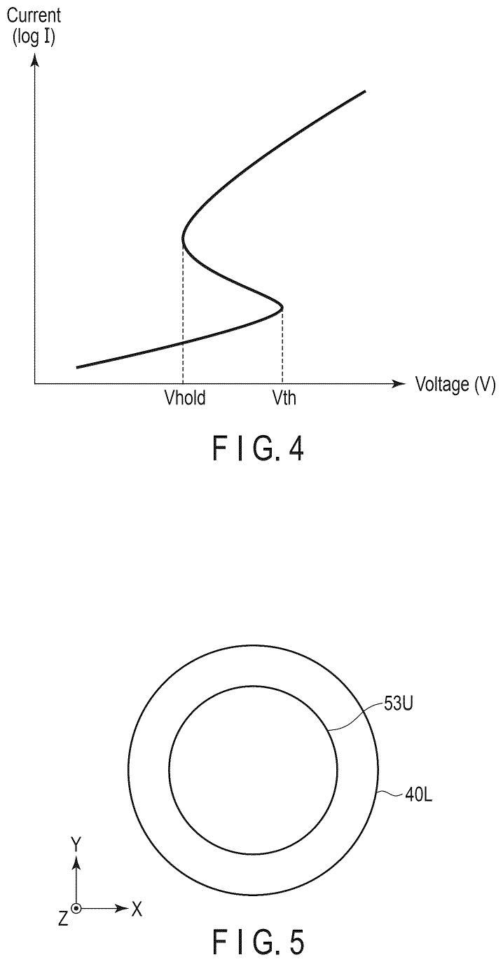

FIG. 4 is a schematic diagram showing current-voltage characteristics of the selector 50.

As shown in FIG. 4, the selector 50 has characteristics that change from an off state to an on state when the voltage applied between the two terminals (between the bottom electrode 52 and the top electrode 53) increases and reaches the threshold voltage Vth, and change from the on state to the off state when the voltage applied between the two terminals decreases to the hold voltage Vhold.

Therefore, when a voltage is applied between each wiring line 10 and the respective wiring line 20 shown in FIG. 1, and the voltage applied between the bottom electrode 52 and the top electrode 53 of respective selector 50 reaches the threshold voltage Vth, the selector 50 is set to the on state, and current flows to the magnetoresistance effect element 40 connected in series to the selector 50, thereby making it possible to perform writing or reading with respect to the magnetoresistance effect element 40.

FIG. 5 is a schematic diagram showing the relationship between the pattern of the lower surface of the magnetoresistance effect element 40 (lower surface of the bottom electrode 42 of the magnetoresistance effect element 40) and the pattern of the upper surface (upper surface of the top electrode 53 of the selector 50) of the selector 50. As shown in FIG. 5, when viewed from the Z direction, the pattern of an upper surface 53U of the top electrode 53 of the selector 50 is located on an inner side of the pattern of the lower surface 40L of the magnetoresistance effect element 40.

The insulating region 60 surrounds the magnetoresistance effect element 40 and the selector 50 described above and includes an insulating layer (first insulating layer) 61, an insulating layer 62, an insulating layer 63, an insulating layer 64, and an insulating layer (second insulating layer) 65.

The insulating layer 61 surrounds a side surface of the top electrode 53 of the selector 50 and has an upper surface at a position lower than that of the upper surface of the top electrode 53. More specifically, the insulating layer 61 surrounds the side surface of the electrode portion 53a of the top electrode 53 and has a lower surface at a position higher than that of the upper surface of the electrode portion 53b of the top electrode 53. Therefore, the insulating layer 61 does not surround the side surface of the upper portion and the side surface of the lower portion of the electrode portion 53a of the top electrode 53, but surrounds the side surface of the middle portion between the upper portion and lower portion of the electrode portion 53a.

The insulating layer 61 is formed of an amphoteric oxide such as aluminum (Al) oxide (typically Al₂O₃), zinc (Zn) oxide (typically ZnO), tin (Sn) oxide (typically SnO₂), lead (Pb) oxide (typically PbO₂) or the like. Amphoteric oxides react with both acids and alkalis and are soluble in both acids and alkalis.

The insulating layer 62 is provided on the upper layer side of the insulating layer 61 and is formed from a material different from that of the insulating layer 61 (for example, silicon oxide). The insulating layer 62 surrounds the entire side surface of the magnetoresistance effect element 40 and also surrounds the side surface of the upper portion of the electrode portion 53a of the top electrode 53 of the selector 50.

The insulating layer 63 is provided on the lower layer side of the insulating layer 61 and is formed from a material different from that of the insulating layer 61 (for example, silicon nitride). The insulating layer 63 surrounds the entire side surface of the selector material layer 51, the bottom electrode 52, and the electrode portion 53b of the top electrode 53 of the selector 50, and also surrounds the side surface of the lower portion of the electrode portion 53a of the top electrode 53 of the selector 50.

The insulating layer 64 is provided on the lower layer side of the insulating layer 63 and is formed from a material different from the material of the insulating layer 61 (for example, silicon oxide).

The insulating layer 64 is provided to cover the side surface of the wiring line 10.

The insulating layer 65 functions as a sidewall insulating layer for the magnetoresistance effect element 40, is provided along the side surface (sidewalls) of the magnetoresistance effect element 40, and is formed of a material different from that of the insulating layer 61 (for example, silicon nitride). The insulating layer 65 is disposed between the magnetoresistance effect element 40 and the insulating layer 62 and surrounds the entire side surface of the magnetoresistance effect element 40.

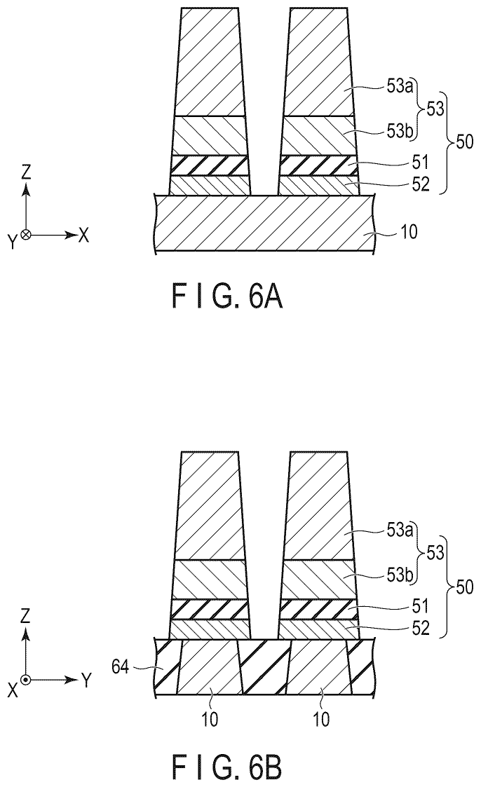

Next, the method of manufacturing the magnetic memory device according to the present embodiment will be described with reference to FIGS. 6A to 11A (cross-sectional views parallel to the X direction) and FIGS. 6B to 11B (cross-sectional views parallel to the Y direction).

First, as shown in FIGS. 6A and 6B, the structure including wiring lines 10, selectors 50, and an insulating layer 64 is formed on an under region (not shown) including a semiconductor substrate (not shown).

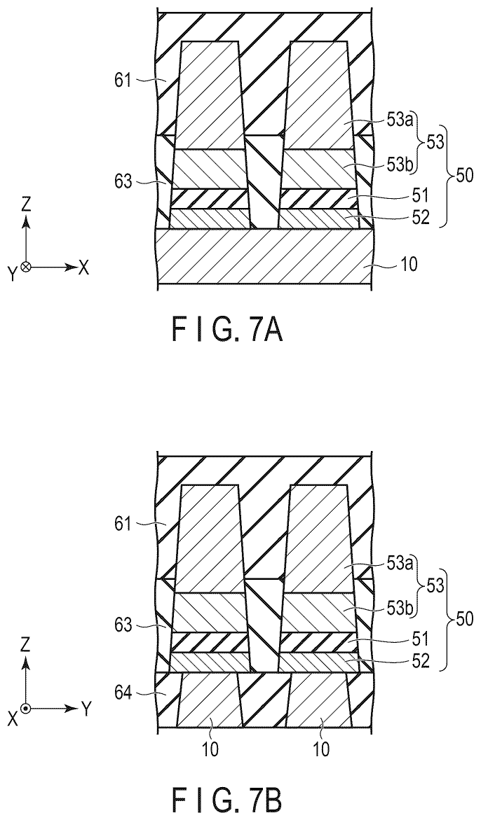

Next, as shown in FIGS. 7A and 7B, an insulating layer 63 is formed so as to cover the structure obtained in the step shown in FIGS. 6A and 6B. Then, the insulating layer 63 is etched back to lower the upper surface of the insulating layer 63. At this time, the etching back is performed so that the position of the upper surface of the insulating layer 63 is higher than the position of the upper surface of the electrode portion 53b of the top electrode 53. Further, on the etched-back insulating layer 63, an insulating layer 61 is formed so as to cover the electrode portion 53a of the top electrode 53.

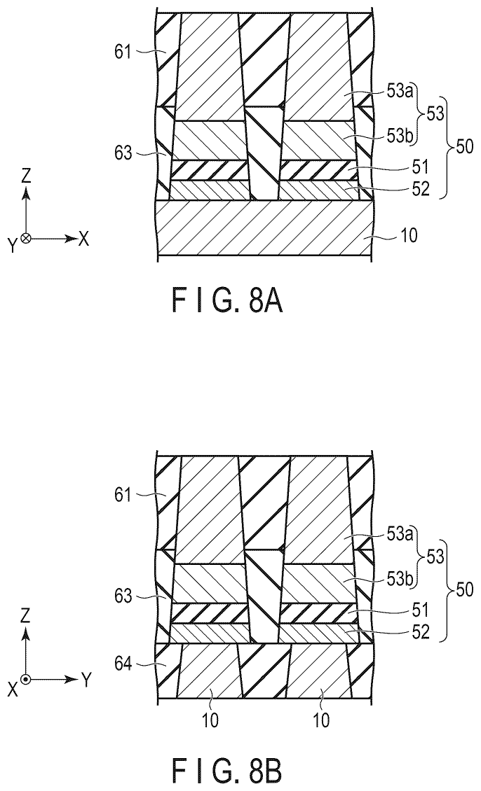

Next, as shown in FIGS. 8A and 8B, the insulating layer 61 is planarized by chemical mechanical polishing (CMP). Thus, the upper surface of the top electrode 53 is exposed.

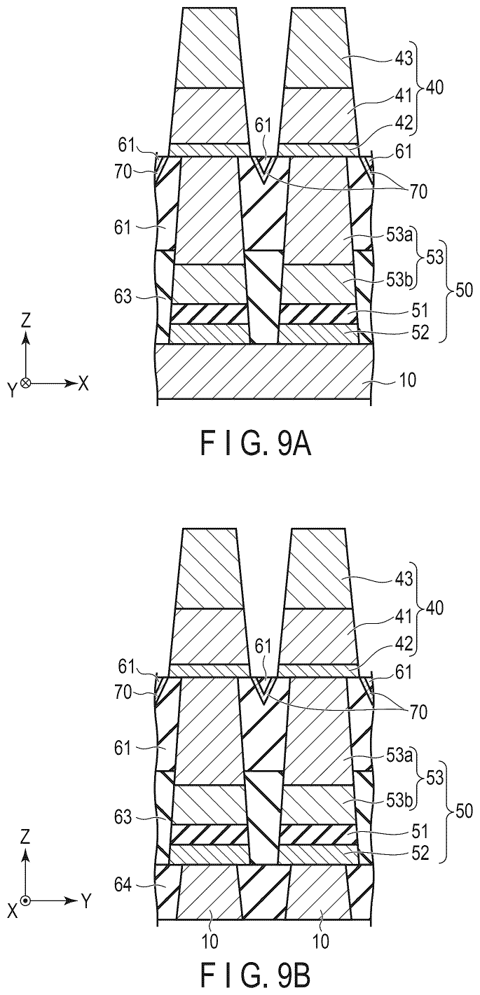

Next, as shown in FIGS. 9A and 9B, a layer for the magnetoresistance effect element 40 is formed on the structure obtained in the step shown in FIGS. 8A and 8B, and thereafter, patterning is carried out by ion beam etching (IBE). More specifically, first, a hard mask layer formed at the uppermost layer of the layer for the magnetoresistance effect element 40 is patterned to form a hard mask pattern. Then, using the hard mask pattern as a mask, the layer for the magnetoresistance effect element 40, which is located on a lower layer side of the hard mask layer is etched by IBE. With this operation, the magnetoresistance effect element 40 is formed. Further, during the above-described IBE process, metal materials and the like etched by IBE are knocked on the insulating layer 61, and thus a residue layer 70 containing metal elements is formed near the upper surface of the insulating layer 61.

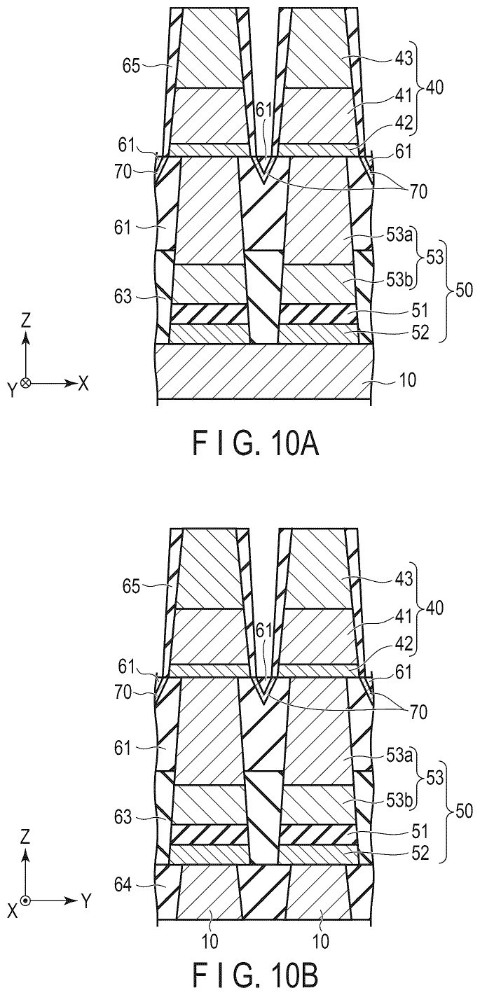

Next, as shown in FIGS. 10A and 10B, an insulating layer 65 is formed so as to cover the structure obtained in the step shown in FIGS. 9A and 9B. More specifically, the insulating layer 65 is formed to cover the entire surface (side surface and upper surface) of the magnetoresistance effect element 40. Further, by anisotropic etching such as reactive ion etching (RIE), the insulating layer 65 formed on the upper surface of the magnetoresistance effect element 40 and on the insulating layer 61 is removed, leaving the portion of the insulating layer 65, which is formed on the side surface (side wall) of the magnetoresistance effect element 40.

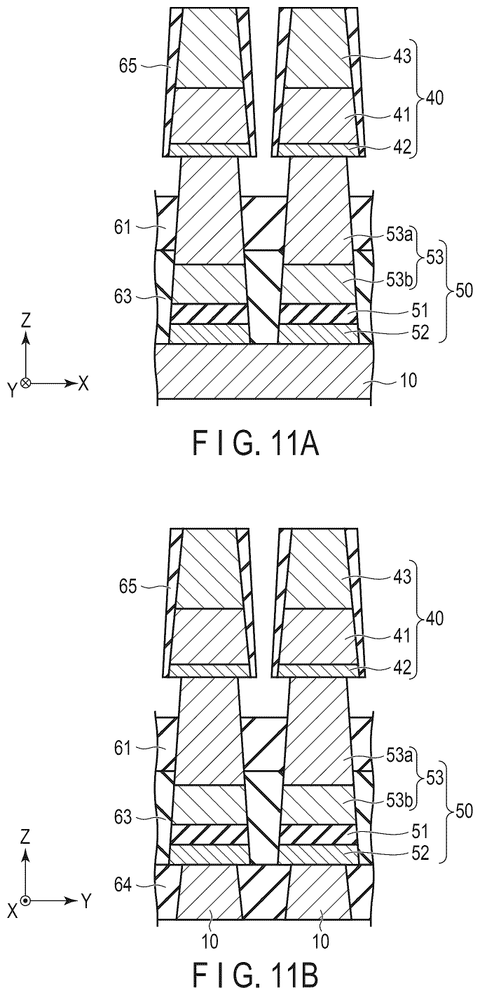

Next, as shown in FIGS. 11A and 11B, the upper portion of the insulating layer 61 is etched using an alkaline solution. More specifically, wet etching is performed using an organic alkaline solution such as a tetramethyl ammonium hydroxide (TMAH) aqueous solution. Note here that the insulating layer 61 is formed from an amphoteric oxide and is therefore etchable by an alkaline solution. During this etching process, the residue layer 70 is also removed along with the upper portion of the insulating layer 61 by lift-off.

During the etching process using the alkaline solution described above, the magnetoresistance effect element 40 is not etched because the side surface of the magnetoresistance effect element 40 is covered by the insulating layer 65 of, for example, silicon nitride, which has alkaline resistance. In particular, the tunnel barrier layer of the magnetoresistance effect element 40 can be etched by an alkaline solution, but the tunnel barrier layer can be protected from the alkaline solution by the insulating layer 65. Further, the bottom electrode 42 and top electrode 43 of the magnetoresistance effect element 40, as well as the electrode portion 53a of the top electrode 53 of the selector 50, are formed from materials having alkaline resistance and are therefore not etched. Furthermore, the insulating layer 61 has a lower surface located at a position higher than that of the upper surface of the electrode portion 53b of the top electrode 53 of the selector 50, and the side surface of the electrode portion 53b are covered by the insulating layer 63. With this structure, even if the electrode portion 53b is formed from a material containing carbon that is soluble in an alkaline solution, the electrode portion 53b can be protected from the alkaline solution.

After the steps shown in FIGS. 11A and 11B, the insulating layer 62 is formed, and thus such a structure as shown in FIGS. 2A and 2B is obtained.

As described above, in this embodiment, the insulating layer 61 formed of an amphoteric oxide is provided, by which it is possible to effectively remove the residue layer 70 without adversely affecting the magnetoresistance effect element 40, as will now be described.

If the residue layer 70 is formed in the region between an adjacent pair of magnetoresistance effect elements 40, the adjacent magnetoresistance effect elements 40 may be electrically connected to each other due to the residue layer 70. In order to avoid this, it is desirable to effectively remove the residue layer 70.

In this embodiment, when forming the pattern of the magnetoresistance effect element 40 by IBE in the step shown in FIGS. 9A and 9B, the side surface of the electrode portion 53a of the top electrode 53 of the selector 50 are covered by the insulating layer 61 formed of an amphoteric oxide. In other words, in a lower region of the region between each pair of magnetoresistance effect elements 40 adjacent to each other, the insulating layer 61 is provided. With this structure, during IBE, the residue layer 70 is formed in the region near the upper surface of the insulating layer 61. Here, note that the insulating layer 61 is formed from an amphoteric oxide that is etchable by an alkaline solution, and therefore the residue layer 70 can be effectively removed along with the insulating layer 61.

Furthermore, with use of an alkaline solution, it is possible to effectively remove the residue layer 70 without adversely affecting the magnetoresistance effect element 40. For merely removing the residue layer 70, a fluoride-based etching solution can also be used. However, when a fluoride-based etching solution is using, it is not possible to reliably protect the magnetoresistance effect element 40 from the etching solution, and for example, the bottom electrode 42 and the like of the magnetoresistance effect element 40 may as well be etched.

In this embodiment, by using an amphoteric oxide as the insulating layer 61 and removing the residue layer 70 together with the insulating layer 61 using an alkaline solution, it is possible to effectively remove the residue layer 70 without adversely affecting the magnetoresistance effect element 40. Therefore, in this embodiment, it is possible to prevent drawbacks such as adjacent magnetoresistance effect elements 40 being electrically connected due to the residue layer 70, and to accurately form the magnetoresistance effect elements 40 without causing adverse effects thereto.

### Second Embodiment

Next, the second embodiment will be described. Note that the basic items are similar to those of the first embodiment, and the explanation of items already described in the first embodiment will be omitted.

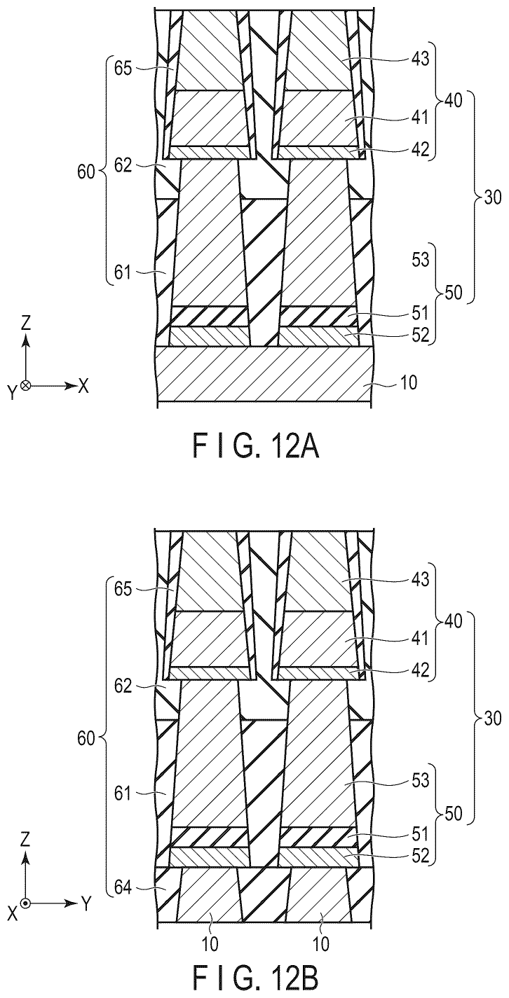

FIGS. 12A and 12B are schematic cross-sectional views each showing a basic structure of a magnetic memory device according to this embodiment.

FIG. 12A is a cross-sectional view parallel to the X direction, and FIG. 12B is a cross-sectional view parallel to the Y direction.

As in the case of the first embodiment, the structure shown in FIGS. 12A and 12B is provided on an under region (not shown) including a semiconductor substrate (not shown), and includes wiring lines 10, memory cells 30 each containing a magnetoresistance effect element 40 and selector (switching element) 50, and an insulating region 60. Note that although not shown in FIGS. 12A and 12B, wiring lines 20 shown in FIG. 1 are usually provided on an upper layer side of the memory cells 30.

In the first embodiment, the top electrode 53 of the selector 50 has a two-layer structure consisting of an electrode portion 53a and an electrode portion 53b, but in this embodiment, the top electrode 53 has a single-layer structure. More specifically, in this embodiment, the top electrode 53 is formed from a conductive material such as titanium nitride (TiN), as in the case of the electrode portion 53a in the first embodiment.

Further, in the first embodiment, the insulating layer 63 is provided between the insulating layer 61 and the insulating layer 64, whereas in this embodiment, the insulating layer 63 is not provided, but an insulating layer 61 formed of an amphoteric oxide similar to that used in the first embodiment is provided on the insulating layer 64.

The basic structure other than that described above is similar to that of the magnetic memory device described in the first embodiment.

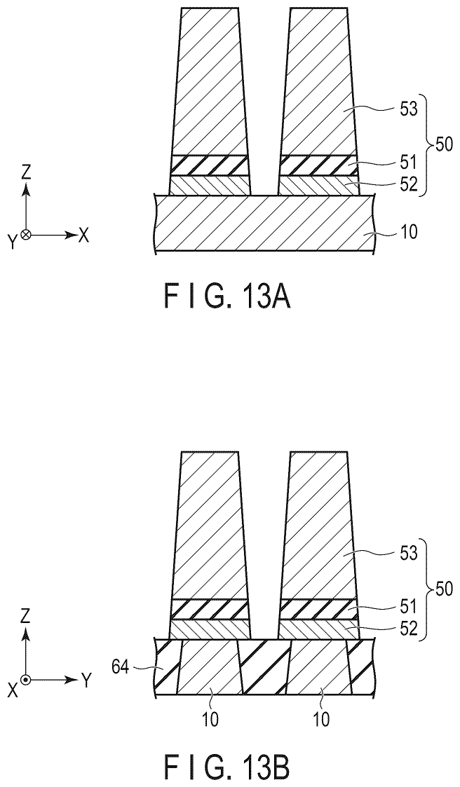

Next, a method of manufacturing the magnetic memory device according to this embodiment will be described with reference to FIGS. 13A to 18A (cross-sectional views parallel to the X direction) and FIGS. 13B to 18B (cross-sectional views parallel to the Y direction).

First, as shown in FIGS. 13A and 13B, a structure containing wiring lines 10, selectors 50, and an insulating layer 64 is formed on an under region (not shown) including a semiconductor substrate (not shown).

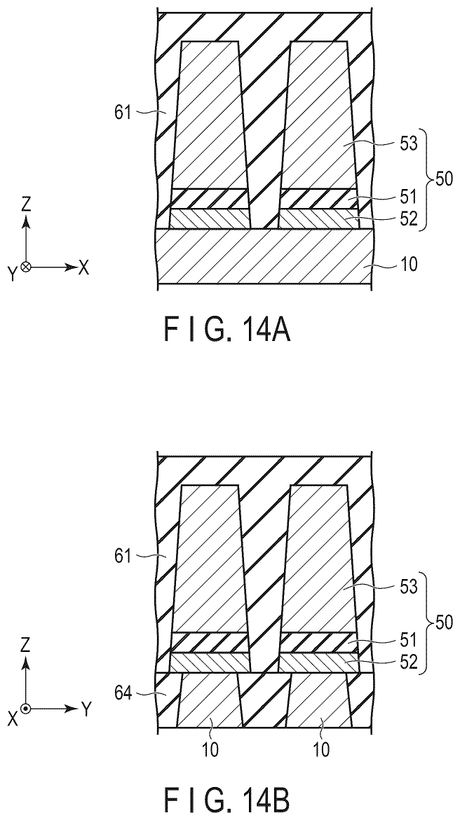

Next, as shown in FIGS. 14A and 14B, an insulating layer 61 is formed so as to cover the structure obtained in the step shown in FIGS. 13A and 13B.

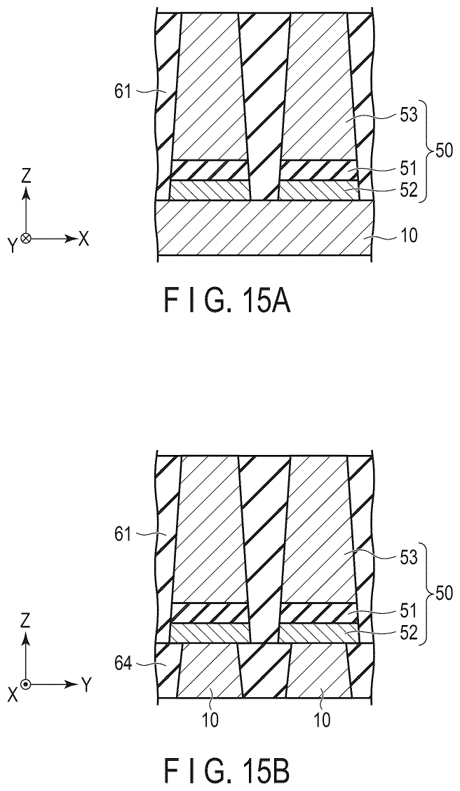

Next, as shown in FIGS. 15A and 15B, the insulating layer 61 is planarized by CMP. With this operation, the upper surface of the top electrode 53 is exposed.

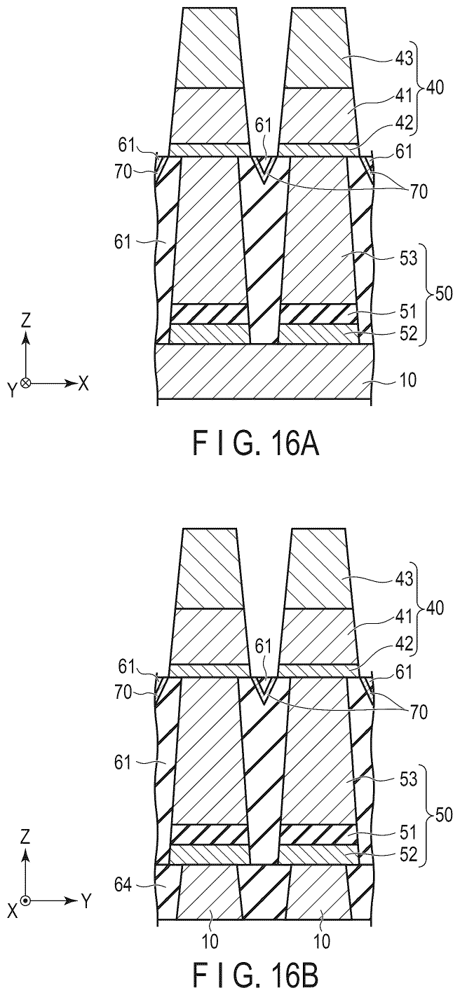

Next, as shown in FIGS. 16A and 16B, a layer for the magnetoresistance effect element 40 is formed on the structure obtained in the step shown in FIGS. 15A and 15B. Further, the resultant is patterned using IBE in a manner similar to that of the step shown in FIGS. 9A and 9B of the first embodiment, and thus the magnetoresistance effect element 40 is formed. At this time, as in the case of the first embodiment, a residue layer 70 is formed near the upper surface of the insulating layer 61.

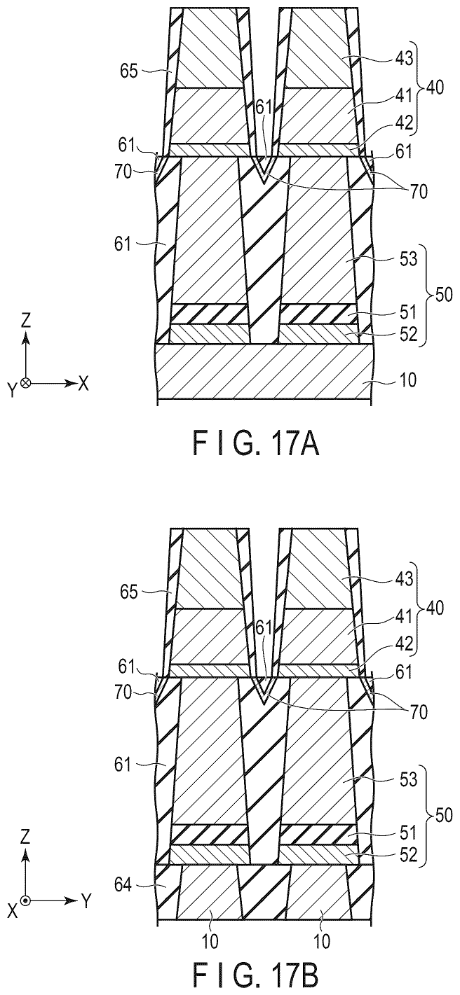

Next, as shown in FIGS. 17A and 17B, an insulating layer 65 is formed on the side surface (side wall) of the magnetoresistance effect element 40 in a manner similar to that of the step shown in FIGS. 10A and 10B of the first embodiment.

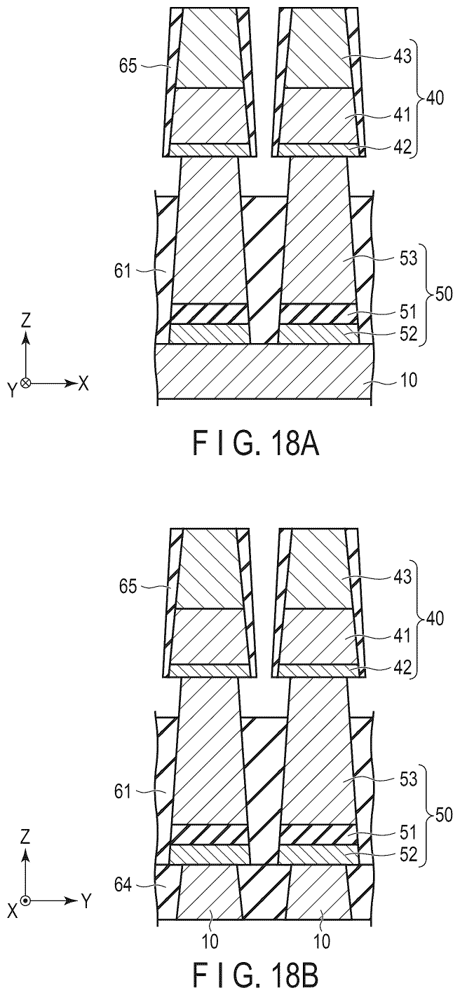

Next, as shown in FIGS. 18A and 18B, an upper portion of the insulating layer 61 is etched using an alkaline solution in a manner similar to that of the step shown in FIGS. 11A and 11B of the first embodiment. In this embodiment as well, the insulating layer 61 is formed from an amphoteric oxide, and thus is etchable by an alkaline solution. Therefore, as in the case of the first embodiment, the residue layer 70 is removed along with the upper portion of the insulating layer 61 by lift-off.

In this embodiment, as in the case of the first embodiment, the side wall of the magnetoresistance effect element 40 is covered by the insulating layer 65 formed of, for example, silicon nitride which has alkali resistance, and therefore the magnetoresistance effect element 40 is not etched during the etching process using an alkali solution described above. Furthermore, the bottom electrode 42 and top electrode 43 of the magnetoresistance effect element 40, as well as the top electrode 53 of the selector 50, are also formed from materials having alkali resistance, and therefore they are not etched.

After the step shown in FIGS. 18A and 18B, the insulating layer 62 is formed, and thus such a structure as shown in FIGS. 12A and 12B is formed.

As described above, in this embodiment as well, by using an amphoteric oxide for the insulating layer 61 and removing the residue layer 70 along with the insulating layer 61 using an alkaline solution, the residue layer 70 can be effectively removed without adversely affecting the magnetoresistance effect element 40. Therefore, in this embodiment as well, it is possible to prevent drawbacks such as adjacent magnetoresistance effect elements 40 being electrically connected due to the residue layer 70, and to accurately form the magnetoresistance effect elements 40 without causing adverse effects thereto.

### Third Embodiment

Next, the third embodiment will be described. Note that the basic items are similar to those of the first embodiment, and the explanation of items already described in the first embodiment will be omitted.

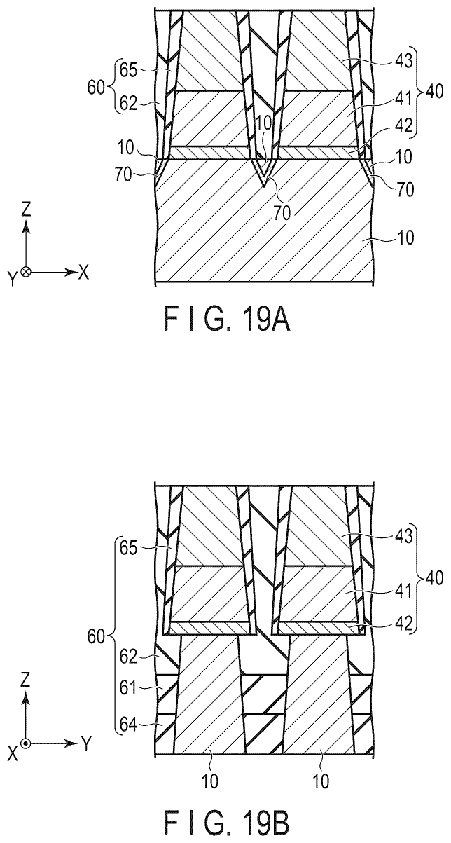

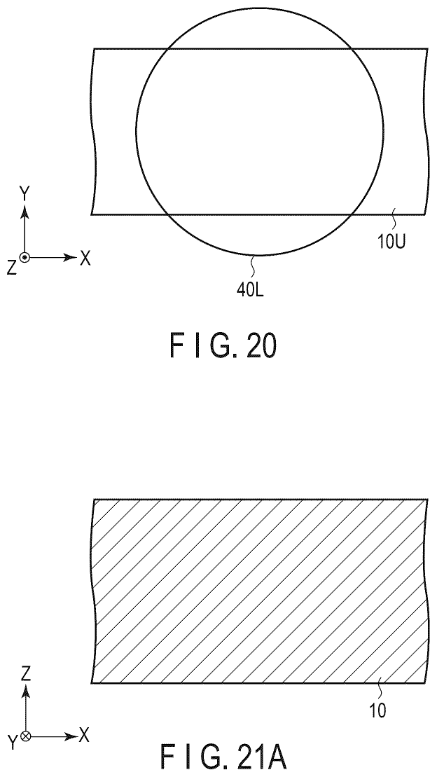

FIGS. 19A and 19B are schematic cross-sectional views each showing a basic structure of a magnetic memory device according to this embodiment. FIG. 19A is a cross-sectional view parallel to the X direction, and FIG. 19B is a cross-sectional view parallel to the Y direction.

As in the cases of the first and second embodiments, the structure shown in FIGS. 19A and 19B is provided on a under region (not shown) including a semiconductor substrate (not shown). Note that in the first and second embodiments, the selectors 50 are connected to the wiring lines 10, respectively, whereas in this embodiment, the magnetoresistance effect elements 40 are connected to the wiring lines 10, respectively. That is, the upper surface of the respective wiring line 10 is connected to the lower surface of the respective magnetoresistance effect element 40. The basic structure of the magnetoresistance effect element 40 is similar to that of the first embodiment.

Note that although not shown in FIGS. 19A and 19B, such a selector 50 as described in the first embodiment may as well be provided on the upper layer side of the magnetoresistance effect element 40. In this case, the wiring lines 20 shown in FIG. 1 may as well be provided on the upper layer side of the memory cells each formed by stacking the magnetoresistance effect element 40 and the selector 50 along the Z direction.

In this embodiment, the insulating layer 61 formed of an amphiphilic oxide similar to that of the first embodiment is provided between the insulating layer 62 and the insulating layer 64. The insulating layer 61 is provided along the two side surfaces (the two side surfaces extending along the X direction) of each of the wiring lines 10. Furthermore, the insulating layer 61 has an upper surface at a position lower than that of the upper surface of the wiring line 10 and a lower surface at a position higher than that of the lower surface of the wiring line 10.

FIG. 20 is a schematic diagram showing the relationship between the pattern of the lower surface of the magnetoresistance effect element 40 (lower surface of the bottom electrode 42 of the magnetoresistance effect element 40) and the pattern of the upper surface of the wiring line 10.

As shown in FIG. 20, when viewed from the Z direction, the width of the pattern of the upper surface 10U of the wiring line 10 in the direction (corresponding to the Y direction) perpendicular to the extending direction of the wiring line 10 (corresponding to the X direction) is less than the maximum width of the pattern of the lower surface 40L of the magnetoresistance effect elements 40 in the direction (corresponding to the Y direction) perpendicular to the extending direction of the wiring line 10 (corresponding to the X direction). For example, when the pattern of the lower surface 40L of the magnetoresistance effect element 40 is a circular pattern, the width of the pattern of the upper surface 10U of the wiring line 10 is less than the diameter of the circular pattern of the lower surface 40L of the magnetoresistance effect element 40.

Further, in this embodiment, the wiring line 10 includes a residue layer 70 containing the metal elements contained in the magnetoresistance effect element 40. That is, the upper surface of the wiring line 10 includes a non-contacting upper surface portion not in contact with the lower surface of the magnetoresistance effect element 40, located on an outer side of the contacting upper surface portion that is in contact with the lower surface of the magnetoresistance effect element 40, and the wiring line 10 includes a residue layer 70 containing the metal elements contained in the magnetoresistance effect element 40 in the vicinity of the non-contacting upper surface portion.

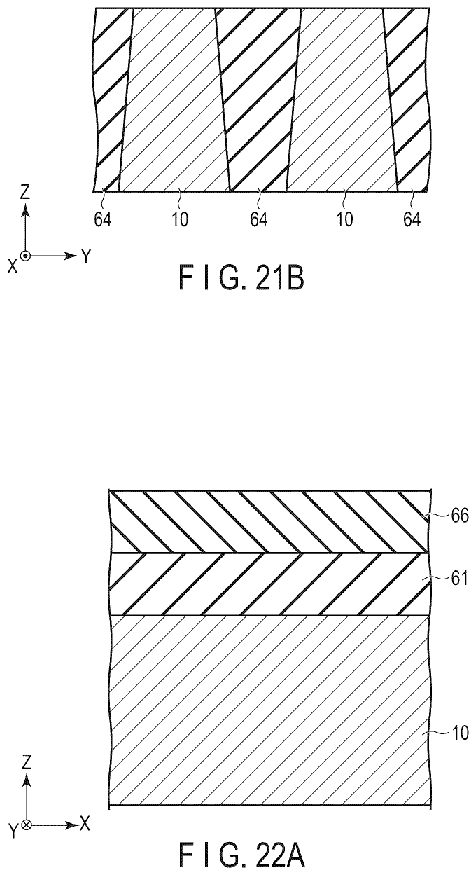

Next, a method of manufacturing the magnetic memory device according to the present embodiment will be described with reference to FIGS. 21A to 26A (cross-sectional views parallel to the X direction) and FIGS. 21B to 26B (cross-sectional views parallel to the Y direction).

First, as shown in FIGS. 21A and 21B, a structure including wiring lines 10 and an insulating layer 64 is formed on an under region (not shown) including a semiconductor substrate (not shown). More specifically, an insulating layer 64 is formed so as to cover the wiring lines 10, and then the insulating layer 64 is planarized by CMP to expose the upper surfaces of the wiring lines 10. With this operation, the structure shown in FIGS. 21A and 21B can be obtained.

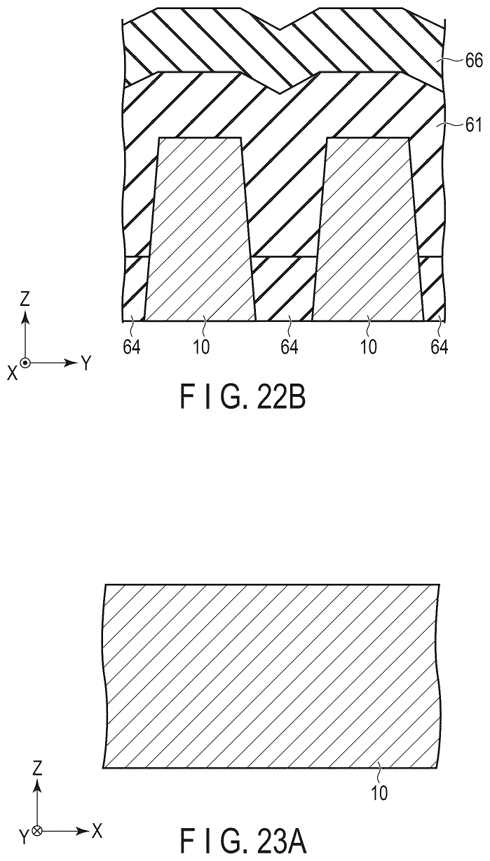

Next, as shown in FIGS. 22A and 22B, the insulating layer 64 is etched back to lower the upper surface of the insulating layer 64. Subsequently, the insulating layer 61 and insulating layer 66 are formed so as to cover the structure obtained in this manner. The insulating layer 66 is used to form mark patterns for alignment.

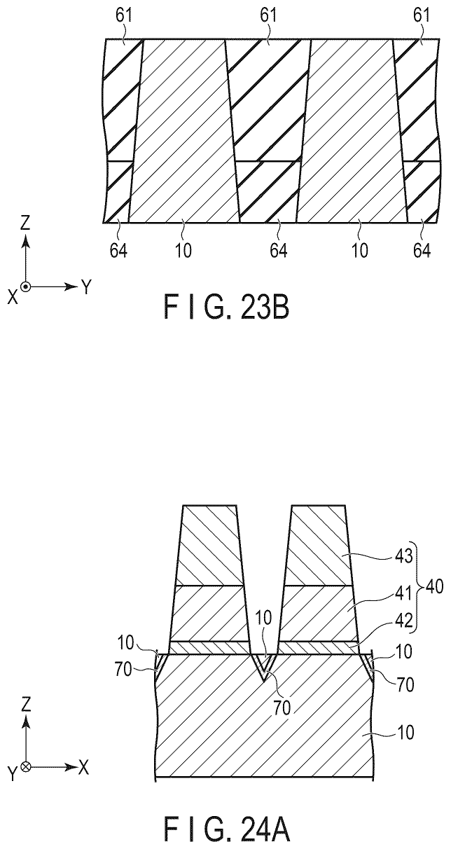

Next, as shown in FIGS. 23A and 23B, the insulating layer 61 and insulating layer 66 are planarized by CMP. With this operation, the upper surfaces of the wiring lines 10 are exposed.

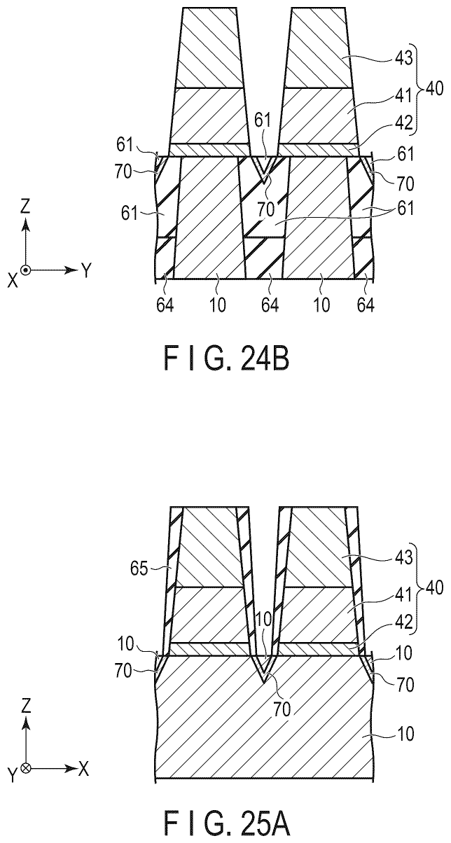

Next, as shown in FIGS. 24A and 24B, a layer for the magnetoresistance effect elements 40 is formed on the structure obtained in the step shown in FIGS. 23A and 23B, and after that, patterning is performed by IBE in a manner similar to that of the step shown in FIGS. 9A and 9B of the first embodiment. Thus, the magnetoresistance effect elements 40 are obtained. Further, metal materials and the like etched by IBE are knocked on the wiring lines 10 and the insulating layer 61, and thus a residue layer 70 containing metal materials is formed near the upper surfaces of the wiring lines 10 and near the upper surface of the insulating layer 61.

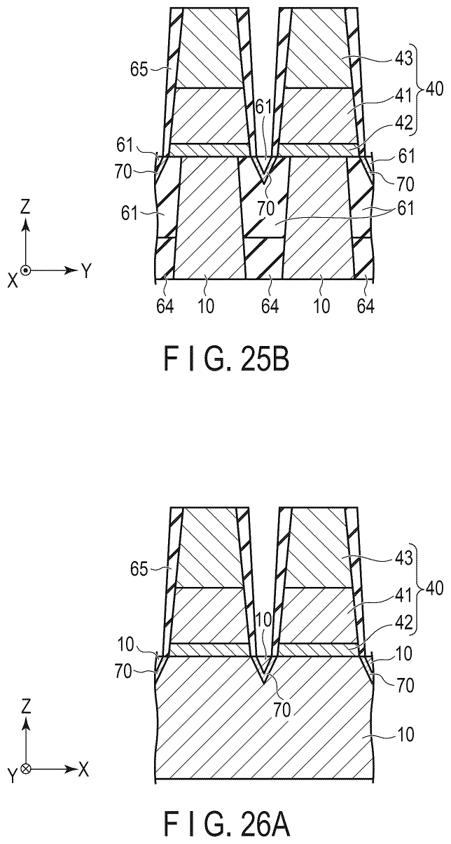

Next, as shown in FIGS. 25A and 25B, an insulating layer 65 is formed on the side surface (side wall) of the magnetoresistance effect element 40 in a manner similar to that of the step shown in FIGS. 10A and 10B of the first embodiment.

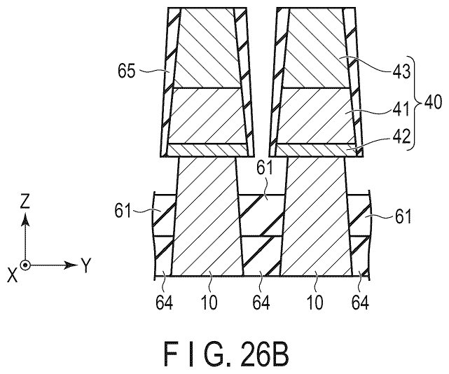

Next, as shown in FIGS. 26A and 26B, the upper portion of the insulating layer 61 is etched using an alkaline solution in a manner similar to that of the step shown in FIGS. 11A and 11B of the first embodiment. In this embodiment as well, the insulating layer 61 is formed of an amphoteric oxide, and thus is etchable by an alkaline solution. Therefore, as in the case of the first embodiment, the residue layer 70 is removed along with the upper portion of the insulating layer 61 by lift-off. Note that the wiring lines 10 are not etched by the alkaline solution, and therefore the residue layer 70 near the upper surface of the wiring line 10 remains.

Further, in this embodiment as well, as in the case of the first embodiment, the side surface of the magnetoresistance effect element 40 are covered by an insulating layer 65 having alkali resistance, and the bottom electrode 42 and top electrode 43 of the magnetoresistance effect element 40 are formed from materials having alkali resistance. Therefore, the magnetoresistance effect element 40 is not etched during the etching process using the alkali solution described above.

After the step shown in FIGS. 26A and 26B, the insulating layer 62 is formed, and thus such a structure as shown in FIGS. 19A and 19B is obtained.

As described above, in this embodiment as well, by using an amphoteric oxide for the insulating layer 61 and removing the residue layer 70 along with the insulating layer 61 using an alkaline solution, the residue layer 70 can be effectively removed without adversely affecting the magnetoresistance effect elements 40. Therefore, in this embodiment as well, it is possible to prevent drawbacks such as adjacent magnetoresistance effect elements 40 being electrically connected due to the residue layer 70, and to accurately form the magnetoresistance effect elements 40 without causing adverse effects thereto.

Furthermore, in this embodiment, the residue layer 70 remains near the upper surface of the wiring line 10, it remains only in the wiring line portion connecting each pair of magnetoresistance effect elements 40 adjacent to each other. Therefore, even if the residue layer 70 remains near the upper surface of the wiring line 10 in this embodiment, no particular problems arise.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is

1. A magnetic memory device comprising:
a magnetoresistance effect element including a first magnetic layer having a variable magnetization direction, a second magnetic layer having a fixed magnetization direction, and a non-magnetic layer provided between the first magnetic layer and the second magnetic layer, and having a structure in which the first magnetic layer, the second magnetic layer, and the non-magnetic layer are stacked;
an electrode having an upper surface connected to a lower surface of the magnetoresistance effect element; and
a first insulating layer formed of an amphoteric oxide, which surrounds a side surface of the electrode and has an upper surface at a position lower than that of the upper surface of the electrode.

2. The device of claim 1, further comprising:
a switching element provided on a lower layer side of the magnetoresistance effect element,
wherein
the electrode functions as a top electrode of the switching element.

3. The device of claim 1, wherein
the electrode includes a first electrode portion connected to a lower surface of the magnetoresistance effect element and a second electrode portion connected to a lower surface of the first electrode portion and formed of a material different from a material of the first electrode portion.

4. The device of claim 3, wherein
the first insulating layer surrounds a side surface of the first electrode portion.

5. The device of claim 3, wherein
the first insulating layer has a lower surface at a position higher than that of an upper surface of the second electrode portion.

6. The device of claim 3, wherein
the second electrode portion contains carbon (C).

7. The device of claim 1, wherein
a pattern of the upper surface of the electrode is located on an inner side a pattern of the lower surface of the magnetoresistance effect element when viewed from a direction in which the first magnetic layer, the second magnetic layer, and the non-magnetic layer are stacked.

8. The device of claim 1, wherein
the amphoteric oxide is selected from aluminum (Al) oxide, zinc (Zn) oxide, tin (Sn) oxide, and lead (Pb) oxide.

9. The device of claim 1, wherein
the magnetoresistance effect element further includes a bottom electrode containing an element selected from titanium (Ti), zirconium (Zr), hafnium (Hf), vanadium (V), niobium (Nb), tantalum (Ta), scandium (Sc), yttrium (Y), and lanthanoid elements.

10. The device of claim 1, wherein
a side surface of the magnetoresistance effect element is surrounded by a second insulating layer formed of a material different from a material of the first insulating layer.

11. A magnetic memory device comprising:
a magnetoresistance effect element including a first magnetic layer having a variable magnetization direction, a second magnetic layer having a fixed magnetization direction, and a non-magnetic layer provided between the first magnetic layer and the second magnetic layer, and having a structure in which the first magnetic layer, the second magnetic layer, and the non-magnetic layer are stacked;
a wiring line having an upper surface connected to a lower surface of the magnetoresistance effect element;
a first insulating layer formed of an amphoteric oxide, which is provided along a side surface of the wiring line and having an upper surface at a position lower than that of the upper surface of the wiring line.

12. The device of claim 11, wherein
the upper surface of the wiring line includes a non-contacting upper surface portion which is not in contact with the lower surface of the magnetoresistance effect element and is located on an outer side of a contacting upper surface portion which is in contact with the lower surface of the magnetoresistance effect element, and
the wiring line contains a metal element contained in the magnetoresistance effect element in a vicinity of the non-contacting upper surface portion.

13. The device of claim 11, wherein
a width of a pattern of the upper surface of the wiring line in a direction perpendicular to an extending direction of the wiring line is less than a maximum width of a pattern of the lower surface of the magnetoresistance effect element in a direction perpendicular to the extending direction of the wiring line, as viewed from a direction in which the first magnetic layer, the second magnetic layer, and the non-magnetic layer are stacked.

14. The device of claim 11, wherein
the amphoteric oxide is selected from aluminum (Al) oxide, zinc (Zn) oxide, tin (Sn) oxide, and lead (Pb) oxide.

15. The device of claim 11, wherein
the magnetoresistance effect element further includes a bottom electrode containing an element selected from titanium (Ti), zirconium (Zr), hafnium (Hf), vanadium (V), niobium (Nb), tantalum (Ta), scandium (Sc), yttrium (Y), and lanthanoid elements.

16. The device of claim 11, wherein
the side surface of the magnetoresistance effect element is surrounded by a second insulating layer formed of a material different from a material of the first insulating layer.
